(19) United States
(12) Patent Application Publication
(10) Pub. No.: US 2017/0067183 A1
(43) Pub. Date: Mar. 9, 2017

(54) METHOD OF MANUFACTURING SiC SINGLE CRYSTAL

(71) Applicant: NIPPON STEEL & SUMITOMO METAL CORPORATION, Tokyo (JP)

(72) Inventors: Kazuaki SEKI, Futtsu-shi, Chiba (JP); Kazuhiko KUSUNOKI, Nishinomiya-shi, Hyogo (JP); Kazuhito KAMEI, Kitakyushu-shi, Fukuoka (JP)

(21) Appl. No.: 15/122,687

(22) PCT Filed: Mar. 12, 2015
(86) PCT No.: PCT/JP2015/057285

§ 371 Date: Aug. 31, 2016

(30) Foreign Application Priority Data
Mar. 13, 2014 (JP) 2014-050322

(51) Int. Cl. C30B 29/36; C30B 19/12; C23C 16/32; C30B 23/02; C30B 25/20; C23C 14/06; C30B 19/04; C30B 19/06

(52) U.S. Cl. CPC C30B 29/36; C30B 19/04; C30B 19/12; C30B 19/062; C30B 23/025; C30B 25/20; C23C 14/0635; C23C 16/325

(57) ABSTRACT

A method of manufacturing an SiC single crystal includes the steps of melting a raw material in a crucible (14) to produce an SIC solution (15); and bringing a crystal growth surface (24A) of an SiC seed crystal (24) into contact with the SiC solution to cause an SiC single crystal to grow on the crystal growth surface. The crystal structure of the SiC seed crystal is the 4H polytype. The off-angle of the crystal growth surface is not smaller than 1° and not larger than 4°. The temperature of the SIC solution during growth of the SiC single crystal is not lower than 1650° C. and not higher than 1850° C. The temperature gradient in a portion of the SiC solution directly below the SiC seed crystal during growth of the SiC single crystal is higher than 0° C./cm and not higher than 19° C./cm.

### TECHNICAL FIELD

The present invention relates to a method of manufacturing an SiC single crystal, and, more particularly, to a method of manufacturing an SiC single crystal by the solution growth method.

### BACKGROUND ART

Silicon carbide (SiC) is a compound semiconductor that is thermally and chemically stable. SiC has a better bandgap, breakdown voltage, electron saturation rate and thermal conductivity than silicon (Si). This makes SiC attractive as a next-generation semiconductor material.

SiC is known as a material exhibiting crystal polytypism. Examples of crystal structures of SiC include the hexagonal 6H and 4H structures, and the cubic 3C structure. SiC single crystals having the 4H crystal structure (hereinafter referred to as 4H—SiC single crystal) has a larger band gap than SiC single crystal with other crystal structures. This makes 4H—SiC single crystal attractive as a next-generation power-device material.

The most popular method of producing SiC single crystal is the sublimation-recrystallization method. However, SiC single crystal produced by the sublimation-recrystallization method can easily develop defects such as micropipes. Such defects adversely affect the properties of a resulting device. Thus, it is desirable to minimize defects.

Another method of producing SiC single crystal is the solution growth method. The solution growth method involves bringing the crystal growth surface of a seed crystal made of SiC single crystal into contact with an SiC solution. The portions of the SiC solution in the vicinity of the seed crystal are supercooled to cause an SiC single crystal to grow on the crystal growth surface of the seed crystal. The solution growth method is disclosed in JP 2009-91222 A, for example.

The solution growth method minimizes micropipes. However, even an SiC single crystal produced by the solution growth method has dislocations which adversely affect the properties of a resulting device. An example of such a dislocation is a threading dislocation. Threading dislocations include, for example, threading screw dislocations (TSDs) and threading edge dislocations (TEDs). A threading screw dislocation propagates in the c-axis direction of the SiC single crystal (i.e. <0001> direction), and has a Burgers vector in the c-axis direction. A threading edge dislocation propagates in the c-axis direction and has a Burgers vector in a direction perpendicular to the c-axis direction. A micropipe is a threading screw dislocation with a large Burgers vector.

To improve the properties of a resulting device, threading dislocations must be reduced. To reduce threading dislocations, threading dislocations may be converted into basal plane defects by step-flow growth, for example. A basal plane defect is a defect formed on the basal plane. Basal plane defects include Frank stacking faults and basal plane dislocations. This method is disclosed in the Journal of the Japanese Association for Crystal Growth, Vol. 40, No. 1 (2013), pp. 25-32 (Non-Patent Document 1), for example.

The above document describes that almost all threading screw dislocations may be converted into Frank stacking faults. It describes that this is because, macroscopically, an SiC single crystal grows in the c-axis direction during step-flow growth, but, microscopically, the crystal grows laterally, i.e. in directions in which macrosteps proceed.

The above document describes that threading edge dislocations may be converted into basal plane dislocations extending in the step-flow direction. Further, it describes that threading edge dislocations may be converted into basal plane dislocations or may not be converted into basal plane dislocations.

The above document further describes that, when a 4H—SiC single crystal (where the crystal growth surface is an Si-face) with a slight slope in the [11-20] direction is used as a seed crystal, the SiC single crystal grows in a step-flow manner in the direction at the off-angle, i.e. in the [11-20] direction. The Burgers vector of threading edge dislocations is denoted by ⅓<11-20>, which, more particularly, includes the following six notations: ⅓[11-20], ⅓[−12-10], ⅓[−2110], ⅓[−1-120], ⅓[1-210], and ⅓[2-1-10]. Almost all the threading edge dislocations having a Burgers vector parallel to the step-flow direction (i.e. ⅓[11-20] and ⅓[−1-120]) are converted into basal plane dislocations. On the other hand, threading edge dislocations with a Burgers vector that is not parallel to the step-flow direction (⅓[−12-10], ⅓[−2110], ⅓[1-210] or ⅓[2-1-10]) are less likely to be converted into basal plane dislocations.

### DISCLOSURE OF THE INVENTION

As described in the above document, the proportion of threading screw dislocations converted into Frank stacking faults is different from the proportion of threading edge dislocations converted into basal plane dislocations. That is, the conversion ratios for threading screw dislocations and threading edge dislocations into basal plane defects are different. As such, threading dislocations in a growing single crystal may be reduced by improving the conversion ratio for threading edge dislocations into basal plane dislocations while maintaining the conversion ratio for threading screw dislocations into Frank stacking faults.

An object of the present invention is to manufacture an SiC single crystal by the solution growth method where the conversion ratio for threading edge dislocations into basal plane dislocations is improved while the conversion ratio for threading screw dislocations into Frank stacking faults is maintained.

A method of manufacturing an SiC single crystal according to an embodiment of the present invention is a method of manufacturing an SiC single crystal by the solution growth method. The method includes the following steps (a) and (b). The step (a) is a production step for heating a raw material in a crucible to melt it to produce an SiC solution. The step (b) is a growth step for bringing a crystal growth surface of an SiC seed crystal into contact with the SiC solution to cause an SiC single crystal to grow on the crystal growth surface. In the above method, a crystal structure of the SiC seed crystal is a 4H polytype. In the above method, an off-angle of the crystal growth surface is not smaller than 1° and not larger than 4°. In the growth step of the above method, a temperature of the SiC solution during growth of the SiC single crystal is not lower than 1650° C. and not higher than 1850° C. In the growth step of the above method, a temperature gradient in a portion of the SiC solution directly below the SiC seed crystal during growth of the SiC single crystal is higher than 0° C./cm and not higher than 19° C./cm.

The method of manufacturing an SiC single crystal according to an embodiment of the present invention improves the conversion ratio for threading edge dislocations into basal plane dislocations while maintaining the conversion ratio for threading screw dislocations into Frank stacking faults.

### BRIEF DESCRIPTION OF THE DRAWINGS

FIG. 1 is a schematic view of an apparatus for manufacturing an SiC single crystal used for the method of manufacturing an SiC single crystal according to an embodiment of the present invention.

FIG. 2 is a conceptual view illustrating dislocations present in an SiC single crystal.

FIG. 3 is a conceptual view illustrating how a threading screw dislocation and a threading edge dislocation are converted into basal plane defects.

FIG. 4A is a picture taken by optical microscopy showing a crystal surface of an SiC single crystal.

FIG. 4B illustrates the relationship between a step-flow direction and a step.

FIG. 5 illustrates the relationship between the Burgers vector of threading edge dislocations and a step.

FIG. 6 is a graph illustrating the conversion ratio for threading screw dislocations into Frank stacking faults against crystal growth temperature, where the off-angle is 1° and the temperature gradient is 11° C./cm.

FIG. 7 is a graph illustrating the conversion ratio for threading edge dislocations into basal plane dislocations against crystal growth temperature, where the off-angle is 1° and the temperature gradient is 11° C./cm.

FIG. 8 is a graph illustrating the conversion ratio for threading screw dislocations into Frank stacking faults against crystal growth temperature, where the off-angle is 4° and the temperature gradient is 11° C./cm.

FIG. 9 is a graph illustrating the conversion ratio for threading edge dislocations into basal plane dislocations against crystal growth temperature, where the off-angle is 4° and the temperature gradient is 11° C./cm.

FIG. 10 is a graph illustrating the conversion ratio for threading edge dislocations into basal plane dislocations against temperature gradient, where the off-angle is 4° and the crystal growth temperature is 1700° C./cm.

### EMBODIMENTS FOR CARRYING OUT THE INVENTION

Now, embodiments of the present invention will be described with reference to the drawings. In the drawings, the same or corresponding parts are labeled with the same characters and their description will not be repeated.

The method of manufacturing an SiC single crystal according to an embodiment of the present invention is a method of manufacturing an SiC single crystal by the solution growth method. The method includes a preparation step, a production step and a growth step. The preparation step prepares a manufacturing apparatus. The production step produces an SIC solution. The growth step brings an SiC seed crystal into contact with the SiC solution and grows an SiC single crystal. The steps will be described in detail below.

[Preparation Step]

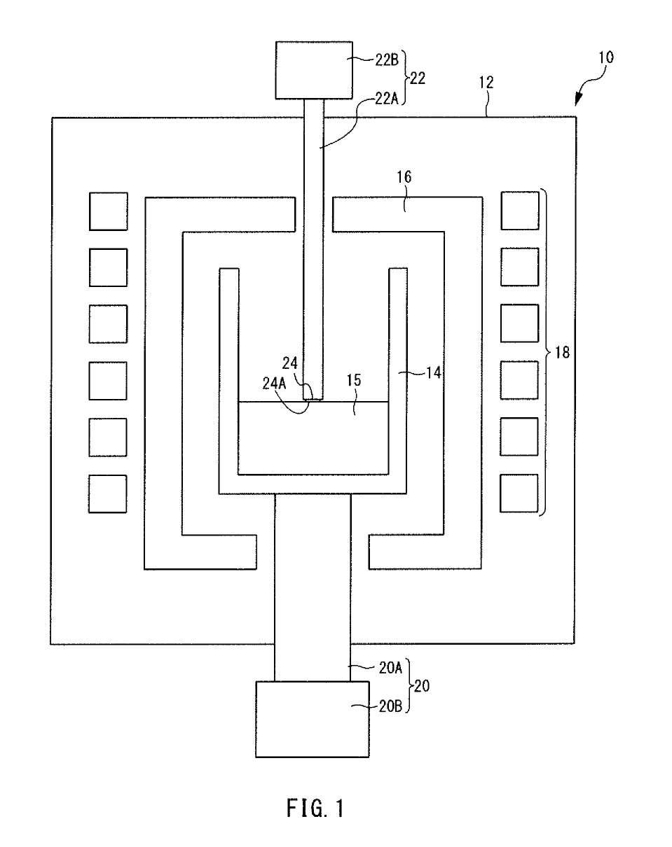

The preparation step prepares a manufacturing apparatus used for the solution growth method. FIG. 1 is a schematic view of a manufacturing apparatus 10 used for the method of manufacturing an SiC single crystal according to an embodiment of the present invention. The manufacturing apparatus 10 shown in FIG. 1 is an example of a manufacturing apparatus used for the solution growth method. The manufacturing apparatus used for the solution growth method is not limited to the manufacturing apparatus 10 shown in FIG. 1.

The manufacturing apparatus 10 includes a chamber 12, a crucible 14, an insulation 16, a heating unit 18, a rotating unit 20, and a lifting unit 22.

The chamber 12 contains the crucible 14. During production of an SiC single crystal, the chamber 12 is cooled.

The crucible 14 contains a raw material for an SiC solution 15. The SiC solution 15 is a solution with carbon (C) dissolved in a melt of Si or an Si alloy. Preferably, the crucible 14 includes carbon. In this case, the crucible 14 serves as a source of carbon for the SiC solution 15.

The insulation 16 is made of an insulating material and surrounds the crucible 14.

The heating unit 18 may be a high-frequency coil, for example. The heating unit 18 surrounds the sidewalls of the insulation 16. The heating unit 18 heats the crucible 14 by induction to produce the SiC solution 15. Further, the heating unit 18 keeps the SiC solution 15 at a crystal growth temperature. The crystal growth temperature is the temperature of the SiC solution 15 during growth of an SiC single crystal, and is represented by the temperature of a portion thereof that is in contact with a crystal growth surface 24A of the SiC seed crystal 24. The crystal growth temperature is in the range of 1650 to 1850° C., and preferably in the range of 1700 to 1800° C.

The rotating unit 20 includes a rotating shaft 20A and a drive source 20B.

The rotating shaft 20A extends in the height direction of the chamber 12 (i.e. in the top-bottom direction in FIG. 1). The top end of the rotating shaft 20A is located within the insulation 16. The crucible 14 is positioned on the top end of the rotating shaft 20A. The bottom end of the rotating shaft 20A is located outside the chamber 12.

The drive source 20B is located below the chamber 12. The drive source 20B is coupled to the rotating shaft 20A. The drive shaft 2011 rotates the rotating shaft 20A about the central axis of the rotating shaft 20A.

The lifting unit 22 includes a seed shaft 22A and a drive source 22B.

The seed shaft 22A extends in the height direction of the chamber 12. The top end of the seed shaft 22A is located outside the chamber 12. The SiC seed crystal 24 is attached to the bottom end surface of the seed shaft 22A.

The drive source 22B is located above the chamber 12. The drive source 22B is coupled to the seed shaft 22A. The drive source 22B lifts and lowers the seed shaft 22A. The drive source 22B rotates the seed shaft 22A about the central axis of the seed shaft 22A.

The preparation step further prepares the SiC seed crystal 24. The SiC seed crystal 24 is made of SiC single crystal. The crystal structure of the SiC seed crystal 24 is the 4H polytype. The crystal growth surface 24A of the SiC seed crystal 24 may be a C-face or an Si-face. The off-angle of the crystal growth surface 24A is in the range of 1° to 4°. The off-angle of the crystal growth surface 24A is the angle formed by a straight line extending perpendicularly to the crystal growth surface 24A and a straight line extending in the c-axis direction. That is, the SiC seed crystal 24 is a 4H—SiC single crystal with a slight slope in the [11-20] direction.

After the manufacturing apparatus 10 and SiC seed crystal 24 have been prepared, the SiC seed crystal 24 is attached to the bottom end surface of the seed shaft 22A.

Next, the crucible 14 is positioned on the rotating shaft 20A within the chamber 12. At this time, the crucible 14 contains a raw material for the SiC solution 15. The raw material may be, for example, Si only, or may be a mixture of Si and one or more other metal elements. Such metal elements include, for example, titanium (Ti), manganese (Mn), chromium (Cr), cobalt (Co), vanadium (V), and iron (Fe). The raw material may be in the form of a plurality of blocks or powder, for example.

[Production Step]

Next, the SiC solution 15 is produced. First, the chamber 12 is filled with inert gas. Then, the heating unit 18 heats the raw material for the SiC solution 15 in the crucible 14 to a temperature above its melting point. If the crucible 14 is made of graphite, heating the crucible 14 causes carbon from the crucible 14 to dissolve in the melt, thereby producing the SiC solution 15. When carbon from the crucible 14 dissolves in the SiC solution 15, the carbon concentration in the SiC solution 15 rises to near the saturation level. In implementations where the crucible 14 does not serve as a source of carbon, a raw material for the SiC solution 15 contains C.

[Growth Step]

Next, the heating unit 18 keeps the SiC solution 15 at the crystal growth temperature. Subsequently, the drive source 22B is used to lower the seed shaft 22A to bring the crystal growth surface 24A of the SiC seed crystal 24 into contact with the SiC solution 15. At this time, the SiC seed crystal 24 may be immersed in the SiC solution 15.

After the crystal growth surface 24A of the SiC seed crystal 24 has been brought into contact with the SiC solution 15, the heating unit 18 keeps the SiC solution 15 at the crystal growth temperature. Further, portions of the SiC solution 15 in the vicinity of the SiC seed crystal 24 are supercooled such that they are supersaturated with SiC. At this time, the temperature gradient in portions of the SiC solution directly below the SiC seed crystal 24 is higher than 0° C./cm and not higher than 19° C./cm. If the temperature gradient is 0° C./cm, crystal growth does not start. If the temperature gradient is above 19° C./cm, supersaturation is high such that a three-dimensional growth develops on a terrace, impairing step-flow growth, which is a two-dimensional growth, such that the conversion ratio for threading edge dislocations into basal plane dislocations decreases. The lower limit of the temperature gradient is preferably 5° C./cm, and more preferably 7° C./cm. The upper limit of the temperature gradient is preferably 15° C./cm and more preferably 11° C./cm.

The method for supercooling portions of the SiC solution 15 in the vicinity of the SiC seed crystal 24 is not particularly limited. For example, the heating unit 18 may be controlled to reduce the temperature in portions of the SiC solution 15 in the vicinity of the SiC seed crystal 24 to a level lower than that in the other portions. Alternatively, portions of the SiC solution 15 in the vicinity of the SiC seed crystal 24 may be cooled by a coolant. More specifically, a coolant may be circulated in the interior of the seed shaft 22A. The coolant may be an inert gas such as helium (He) or argon (Ar), for example. Circulating the coolant in the seed shaft 22 cools the SiC seed crystal 24. When the SiC seed crystal 24 is cooled, portions of the SiC solution 15 in the vicinity of the SiC seed crystal 24 are cooled, as well.

With portions of the SiC solution 15 in the vicinity of the SiC seed crystal 24 supersaturated with SiC, the SiC seed crystal 24 and SiC solution 15 (or crucible 14) are rotated. Rotating the seed shaft 22A rotates the SiC seed crystal 24. Rotating the rotating shaft 20A rotates the crucible 14. The SiC seed crystal 24 may be rotated in the direction opposite to that for the crucible 14, or in the same direction. The rotation rate may be constant or may vary. While being rotated, the seed shaft 22A is gradually lifted. At this time, SiC single crystal grows on the crystal growth surface of the SiC seed crystal 24, which is in contact with the SiC solution 15. The seed shaft 22A may be rotated without being lifted, or may not be lifted nor rotated.

[SiC Single Crystal Produced]

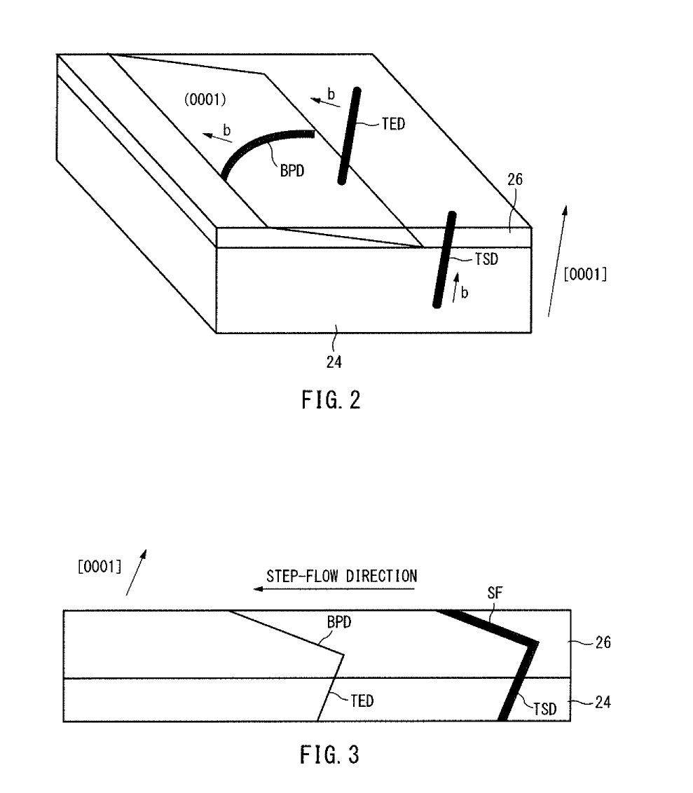

An SiC single crystal produced by the above method will be described with reference to FIGS. 2 and 3. FIG. 2 is a conceptual view illustrating threading screw dislocations and threading edge dislocations present in an SiC single crystal. FIG. 3 is a conceptual view illustrating how threading screw dislocations and threading edge dislocations are converted into basal plane defects.

The above method causes the SiC single crystal 26 to grow on the crystal growth surface 24A of the SiC seed crystal 24. As shown in FIG. 2, threading screw dislocations TSD and threading edge dislocations TED are present in the SiC single crystal 26. A threading screw dislocation TSD propagates in the c-axis direction of the SiC single crystal 24 (<0001> direction), and has a Burgers vector b in the c-axis direction. A threading edge dislocation TED propagates in the c-axis direction and has a Burgers vector b perpendicular to the c-axis direction.

If the above method is employed, threading screw dislocations TSD are converted into Frank stacking faults SF, as shown in FIG. 3. This is presumably because, for example, macroscopically, an SiC single crystal grows in the c-axis direction during step-flow growth, but, microscopically, the crystal grows laterally, i.e. in directions in which macrosteps proceed.

If the above method is employed, threading edge dislocations TED are converted into basal plane dislocations BPD, as shown in FIG. 3. Threading edge dislocations TED may be converted into basal plane dislocations BPD or may not be converted into basal plane dislocations BPD. It is supposed that the SiC seed crystal 24 is a 4H—SiC single crystal with a slight slope in the [11-20] direction and the crystal growth surface 24A is an Si-face. Then, the SiC single crystal 26 grows in a step-flow manner in the direction at the off-angle, i.e. in the [11-20] direction. The Burgers vector of the threading edge dislocations TED is denoted by ⅓<11-20>, which, more particularly, includes the following six notations: ⅓[11-20], ⅓[−12-10], ⅓[−2110], ⅓[−1-120], ⅓[1-210], and ⅓[2-1-10]. Almost all the threading edge dislocations TED having a Burgers vector parallel to the step-flow direction (i.e. ⅓[11-20] and ⅓[−1-120]) are converted into basal plane dislocations BPD. On the other hand, threading edge dislocations TED with a Burgers vector that is not parallel to the step-flow direction (⅓[−12-10], ⅓[−2110], ⅓[1-210] or ⅓[2-1-10]) are less likely to be converted into basal plane dislocations BPD.

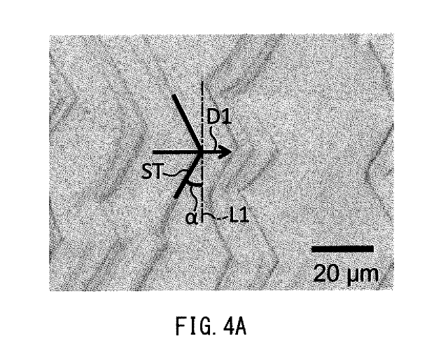

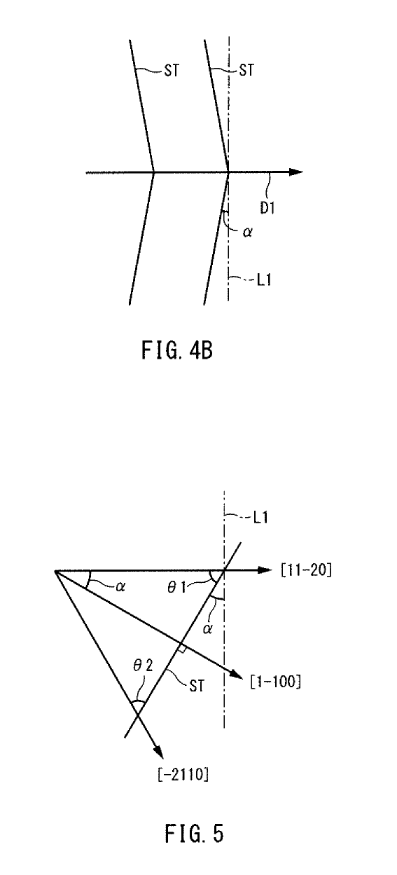

If the method of manufacturing an SiC single crystal according to an embodiment of the present invention is employed, threading edge dislocations TED can be converted into basal plane dislocations BPD more easily. The reasons therefor will be described with reference to FIGS. 4A, 4B and 5. FIG. 4A is a picture taken by optical microscopy showing a crystal surface of an SiC single crystal 26. FIG. 4B illustrates the relationship between a step-flow direction and a step. FIG. 5 illustrates the relationship between the Burgers vector of threading edge dislocations and a step.

The SiC single crystal 26 grows in a step-flow manner and thus is formed on top of the crystal growth surface 24A of the SiC seed crystal 24. Thus, as shown in FIGS. 4A and 4B, the SiC single crystal 26 has steps ST. A step ST is a step in a crystal that can be observed on a crystal surface by optical microscopy, as shown in FIG. 4A. The step ST is inclined relative to a reference line L1 extending perpendicularly to the step-flow direction D1 as viewed in a direction perpendicular to the crystal growth surface 24A, as shown in FIGS. 4A and 4B.

If the method of manufacturing an SiC single crystal according to an embodiment of the present invention is employed, the inclination angle α of the step ST relative to the reference line L1 can be adjusted to an appropriate level. This improves the conversion ratio for threading edge dislocations TED into basal plane dislocations BPD. This is presumably because of the following reasons, for example.

As discussed above, if the SiC seed crystal 24 is a 4H—SiC single crystal with a slight slope in the [11-20] direction and the crystal growth surface 24A is an Si-face, the Burgers vector of the threading edge dislocations TED is denoted by ⅓<11-20>. More particularly, this includes the following six notations: ⅓[11-20], ⅓[−12-10], ⅓[−2110], ⅓[−1-120], ⅓[1-210], and ⅓[2-1-10]. Each of these Burgers vectors is rotated from another by 60° about the c-axis. That is, two adjacent Burgers vectors about the c-axis form an angle of 60°. FIG. 5 shows a Burgers vector in ⅓[11-20] and a Burgers vector in ⅓[02110].

The angle formed by two adjacent Burgers vectors about the c-axis is divided by the <1-100> direction into two halves. FIG. 5 shows [1-100] that equally divides into two halves the angle formed by a Burgers vector in ⅓[11-20] and a Burgers vector in ⅓[−2110].

Immediately after initiation of crystal growth, a step perpendicular to the step-flow direction formed on the SiC seed crystal 24 by polishing is formed. Thus, threading edge dislocations TED having a Burgers vector parallel to the step-flow direction (⅓[11-20] and ⅓[−1-120]) are converted into basal plane dislocations BPD.

When crystal growth further progresses, a step ST inclined relative to the reference line L1 is formed, as shown in FIG. 5. FIG. 5 shows an implementation where the step ST perpendicularly crosses the [1-100] direction, i.e. the angle θ1 at which the step ST crosses the [11-20] direction is equal to the angle θ2 at which the step ST crosses the [−2110] direction. The angles θ1 and θ2 need not be equal. As discussed above, the angle formed by <11-20> and <1-100> is 30°. The inclination angle α is only required to be larger than 15° and smaller than 90°.

As the step ST is formed, threading edge dislocations TED having a Burgers vector that is not parallel to the step-flow direction (i.e. ⅓[−12-10], ⅓[−2110], ⅓[1-210], or ⅓[2-1-10]) are converted into basal plane dislocations BPD. This will improve the conversion ratio for threading edge dislocations TED into basal plane dislocations BPD as a whole.

The method of manufacturing an SiC single crystal according to an embodiment of the present invention produces an SiC single crystal with few threading screw dislocations and threading edge dislocations. Thus, if such an SiC single crystal is used as a seed crystal and an SiC single crystal is produced by the sublimation-recrystallization method or high-temperature CVD method, an SiC single crystal of high quality can be produced at high growth rate.

For the sublimation-recrystallization method, a seed crystal made of SiC single crystal and SiC crystal powder that provides a raw material for an SiC single crystal are placed in the crucible and heated in an atmosphere of an inert gas, such as argon gas. At this time, the temperature gradient is set such that the seed crystal is at a somewhat lower temperature than the raw material powder. The raw material is diffused and transported toward the seed crystal by a density gradient formed by the temperature gradient after sublimation. Growth of SiC single crystal occurs as raw material gas that has reached the seed crystal is recrystallized on the seed crystal.

For the high-temperature CVD method, a seed crystal made of SiC single crystal is positioned on a pedestal supported by a rod-shaped member in a vacuum container and a raw material gas of SiC is supplied from below the seed crystal to cause an SiC single crystal to grow on a surface of the seed crystal.

### Examples

SiC single crystals were produced under various manufacturing conditions. The conversion ratio for threading screw dislocations into Frank stacking faults and the conversion ratio for threading edge dislocations into basal plane dislocations for each of the produced SiC single crystals were measured.

SiC single crystals were produced under the manufacturing conditions shown in Table 1.

TABLE 1

| | Crystal structure of | Crystal growth | Crystal growth | | Temperature | Composition of |
|---|---|---|---|---|---|---|
| | SiC seed crystal | temperature (° C.) | surface | Off-angle (°) | gradient (° C./cm) | SiC solution |
| Example 1 | 4H | 1700 | Si | 4 | 11 | Si |
| Example 2 | 4H | 1700 | Si | 1 | 11 | Si |
| Example 3 | 4H | 1800 | Si | 1 | 11 | Si |
| Example 4 | 4H | 1700 | Si | 4 | 7 | Si—Ti |
| Example 5 | 4H | 1800 | C | 4 | 7 | Si—Ti |
| Example 6 | 4H | 1800 | Si | 4 | 11 | Si |
| Example 7 | 4H | 1700 | Si | 4 | 19 | Si |
| Comparative Ex. 1 | 4H | 1700 | Si | on-axis | 7 | Si |
| Comparative Ex. 2 | 4H | 1700 | Si | 8 | 7 | Si |
| Comparative Ex. 3 | 4H | 1600 | Si | 4 | 11 | Si |
| Comparative Ex. 4 | 4H | 1900 | Si | 4 | 11 | Si |
| Comparative Ex. 5 | 4H | 1700 | Si | 4 | 22 | Si |
| Comparative Ex. 6 | 4H | 1800 | Si | on-axis | 11 | Si |
| Comparative Ex. 7 | 4H | 1900 | Si | 1 | 11 | Si |
| Comparative Ex. 8 | 4H | 1630 | Si | 1 | 11 | Si |

The manufacturing conditions for Examples 1 to 7 were within the ranges of the present invention. The manufacturing conditions for Comparative Examples 1 to 8 were outside the ranges of the present invention.

The inclination angle α, the step height, the conversion ratio for threading screw dislocations into Frank stacking faults and the conversion ratio for threading edge dislocations into basal plane dislocations were measured for each of the produced SiC single crystals. Based on these measurements, dislocation conversion and surface structure were evaluated, and general evaluation was made. The results are shown in Table 2.

TABLE 2

| | | | TSD conversion | TED conversion | Dislocation | Surface | General |
|---|---|---|---|---|---|---|---|
| | α (°) | Step height (nm) | ratio (%) | ratio (%) | conversion | structure | evaluation |
| Example 1 | 15 | 130 | 99 | 50 | ⊚ | ◯ | ◯ |
| Example 2 | 30 | 100 | 90 | 78 | ⊚ | ⊚ | ⊚ |
| Example 3 | 20 | 80 | 90 | 50 | ⊚ | ◯ | ◯ |
| Example 4 | 30 | 200 | 99 | 58 | ⊚ | ⊚ | ⊚ |
| Example 5 | 30 | 60 | 70 | 56 | ◯ | ⊚ | ◯ |
| Example 6 | 20 | 110 | 99 | 55 | ⊚ | ◯ | ◯ |
| Example 7 | 15 | 180 | 99 | 50 | ⊚ | ◯ | ◯ |
| Comparative Ex. 1 | ≈0 | 10 | 5 | 15 | X | X | X |
| Comparative Ex. 2 | 10 | 350 | 99 | 20 | X | X | X |
| Comparative Ex. 3 | 30 | 225 | — | — | X | ⊚ | X |
| Comparative Ex. 4 | 5 | 2 | 70 | 9 | X | X | X |
| Comparative Ex. 5 | 15 | 300 | 99 | 20 | X | ◯ | X |
| Comparative Ex. 6 | ≈0 | 25 | 3 | 10 | X | X | X |
| Comparative Ex. 7 | 10 | 1.5 | 5 | 25 | X | X | X |
| Comparative Ex. 8 | 30 | 120 | — | — | X | ⊚ | X |

⊚: excellent
◯: good
X: not acceptable

The inclination angle α was measured by observing a surface of each SiC single crystal by optical microscopy. The step height was measured by observing a surface of each SiC single crystal by atomic force microscopy. The conversion ratio for threading screw dislocations into Frank stacking faults (i.e. TSD conversion ratio) and the conversion ratio for threading edge dislocations into basal plane dislocations (i.e. TED conversion ratio) were measured by observing etch pits exhibiting threading screw dislocations and etch pits exhibiting threading edge dislocations. That is, the conversion rate for threading screw dislocations and that for threading edge dislocations were separately calculated by calculating the difference between the number of etch pits formed on the surface of an SiC single crystal etched by molten KOH and the number of etch pits formed on the surface of the SiC seed crystal etched molten KOH, and dividing this difference by the number of etch pits formed on the surface of the SiC seed crystal etched by molten KOH. Etching occurred for a duration of 3 to 4 minutes. The temperature of the molten KOH was 500° C. The number of etch pits exhibiting threading screw dislocations and that for threading edge dislocations were determined by observing a surface of a crystal etched by molten KOH by optical microscopy.

Dislocation conversion was evaluated using the following standards. In Table 2, “⊚” (excellent) means a TSD conversion ratio not lower than 90% and a TED conversion ratio not lower than 50%. “∘” (good) means a TSD conversion ratio lower than 90% and a TED conversion ratio not lower than 50%. “x” (not acceptable) means that none of the above conditions was met. For Comparative Examples 3 and 8, it was difficult to observe etch pits due to, for example, an increase in dislocations and the presence of heterogeneous phases, making it impossible to measure the TSD conversion ratio and TED conversion ratio.

Surface structure was evaluated using the following standards. In Table 2, “⊚” (excellent) means an inclination angle α not smaller than 30° and smaller than 90°. “∘” (good) means an inclination angle α not smaller than 15° and smaller than 30°. “x” (not acceptable) means an inclination angle α smaller than 15°.

General evaluation was made using the following standards. In Table 2, “⊚” (excellent) means that both the conversion ratio and surface structure were classified under “⊚”. “∘” (good) means that none of the dislocation conversion and surface structure were classified under “x” and one of them was classified under “∘”. “x” (not acceptable) means that the dislocation conversion or surface structure was classified under “x”.

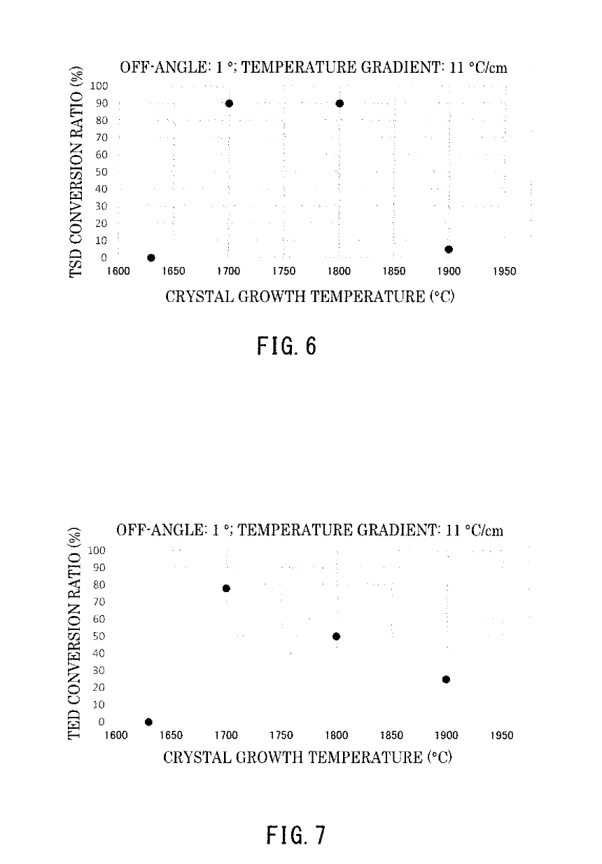

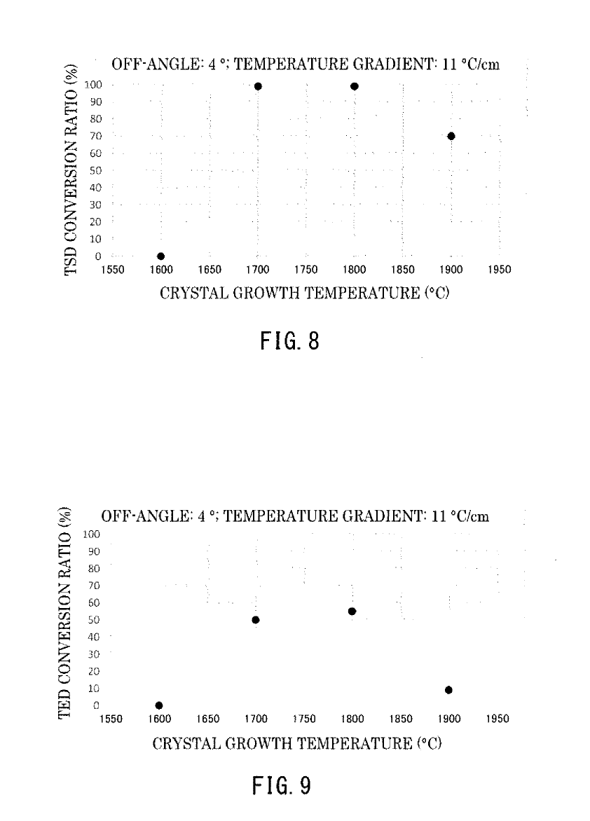

FIG. 6 is a graph illustrating the relationship between the crystal growth temperature and the conversion ratio for threading screw dislocations into Frank stacking faults for Examples 2 and 3 and Comparative Examples 7 and 8. FIG. 7 is a graph illustrating the relationship between the crystal growth temperature and the conversion ratio for threading edge dislocations into basal plane dislocations for Examples 2 and 3 and Comparative Examples 7 and 8. FIG. 8 is a graph illustrating the relationship between the crystal growth temperature and the conversion ratio for threading screw dislocations into Frank stacking faults for Examples 1 and 6 and Comparative Examples 3 and 4. FIG. 9 is a graph illustrating the relationship between the crystal growth temperature and the conversion ratio for threading edge dislocations into basal plane dislocations for Examples 1 and 6 and Comparative Examples 3 and 4.

As shown in FIGS. 6 to 9, at crystal growth temperatures in the range of 1650° C. to 1850° C., the conversion ratio for threading screw dislocations into Frank stacking faults and the conversion ratio for threading edge dislocations into basal plane dislocations were improved.

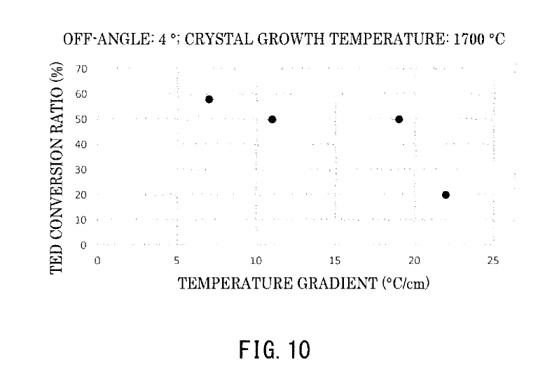

FIG. 10 is a graph illustrating the relationship between the temperature gradient and the conversion ratio for threading edge dislocations into basal plane dislocations for Examples 1, 4 and 7 and Comparative Example 5. As shown in FIG. 10, at temperature gradients higher than 0° C./cm and not higher than 19° C./cm, the conversion ratio for threading edge dislocations into basal plane dislocations was improved.

Although embodiments of the present invention have been described in detail, these embodiments are merely examples, and the present invention is not limited in any way by the above embodiments.

1. A method of manufacturing an SiC single crystal by a solution growth method, comprising:
a production step for heating a raw material in a crucible to melt it to produce an SIC solution; and
a growth step for bringing a crystal growth surface of an SIC seed crystal into contact with the SiC solution to cause an SiC single crystal to grow on the crystal growth surface,
wherein a crystal structure of the SiC seed crystal is a 4H polytype,
an off-angle of the crystal growth surface is not smaller than 1° and not larger than 4°,
in the growth step,
a temperature of the SiC solution during growth of the SiC single crystal is not lower than 1650° C. and not higher than 1850° C., and
a temperature gradient in a portion of the SIC solution directly below the SIC seed crystal during growth of the SiC single crystal is higher than 0° C./cm and not higher than 19° C./cm.

2. The method of manufacturing an SIC single crystal according to claim 1, wherein the temperature of the SIC solution during growth of the SIC single crystal is not lower than 1700° C. and not higher than 1800° C.

3. The method of manufacturing an SiC single crystal according to claim 1, wherein the crystal growth surface is a C-face.

4. A method of manufacturing an SiC single crystal by a sublimation-recrystallization method or high-temperature CVD method, comprising:
preparing an SIC seed crystal; and
causing an SiC single crystal to grow on the SiC seed crystal,
wherein the SiC seed crystal is produced by the method according to claim 1.

5. An SiC single crystal having grown on a crystal growth surface of an SIC seed crystal in a step-flow manner in an [11-20] direction,
wherein, as viewed in a direction perpendicular to the crystal growth surface, an angle formed by a step and a reference line extending perpendicularly to an [11-20] direction is larger than 15° and smaller than 90°, and,
as viewed in a direction parallel to the crystal growth surface, a height of a bunched step is larger than 2 nm and not larger than 200 nm.

6. The method of manufacturing an SiC single crystal according to claim 2, wherein the crystal growth surface is a C-face.

7. A method of manufacturing an SiC single crystal by a sublimation-recrystallization method or high-temperature CVD method, comprising:
preparing an SIC seed crystal; and
causing an SIC single crystal to grow on the SiC seed crystal,
wherein the SIC seed crystal is produced by the method according to claim 2.

8. A method of manufacturing an SIC single crystal by a sublimation-recrystallization method or high-temperature CVD method, comprising:
preparing an SIC seed crystal; and
causing an SiC single crystal to grow on the SiC seed crystal,
wherein the SIC seed crystal is produced by the method according to claim 3.

9. A method of manufacturing an SiC single crystal by a sublimation-recrystallization method or high-temperature CVD method, comprising:
preparing an SiC seed crystal; and
causing an SiC single crystal to grow on the SiC seed crystal,
wherein the SIC seed crystal is produced by the method according to claim 6.
